(19) United States
(12) Patent Application Publication
(10) Pub. No.: US 2018/0358477 A1
(43) Pub. Date: Dec. 13, 2018

(54) TRENCH TYPE JUNCTION BARRIER SCHOTTKY DIODE AND MANUFACTURING METHOD THEREOF

(71) Applicants: NA REN, LOS ANGELES, CA (US); ZHENG ZUO, CULVER CITY, CA (US); RUIGANG LI, FREMONT, CA (US)

(72) Inventors: NA REN, LOS ANGELES, CA (US); ZHENG ZUO, CULVER CITY, CA (US); RUIGANG LI, FREMONT, CA (US)

(73) Assignee: AZ Power, Inc, CULVER CITY, CA (US)

(21) Appl. No.: 16/005,547

(22) Filed: Jun. 11, 2018

Related U.S. Application Data
(60) Provisional application No. 62/517,703, filed on Jun. 9, 2017.

(51) Int. Cl. H01L 29/872; H01L 29/16; H01L 29/66; H01L 21/265

(52) U.S. Cl. CPC H01L 29/872; H01L 21/26513; H01L 29/6606; H01L 29/1608

(57) ABSTRACT

In one aspect, a method for manufacturing a Schottky diode may include steps of providing a substrate, depositing an epitaxial layer on top of the substrate, forming one or more trenches on top of the epitaxial layer, producing an implantation region at a bottom portion of each trench, providing an ohmic contact metal on an opposite site of the substrate, and depositing a Schottky contact metal on top of the epitaxial layer and filled into each trench to form a Schottky junction between the Schottky contact metal and the epitaxial layer, and between each trench and the epitaxial layer. In one embodiment, the substrate is made by N⁺ type Silicon Carbide (SiC) and the epitaxial layer is made by N⁻ type SiC. In another embodiment, the step of producing an implantation region includes a step of doping P-type impurity into the bottom of each trench.

### CROSS-REFERENCE TO RELATED APPLICATIONS

This application claims priority under 35 U.S.C. § 119 (e) to U.S. Provisional Patent Application Ser. No. 62/517,703, filed on Jun. 9, 2017, the entire contents of which are hereby incorporated by reference.

### FIELD OF THE INVENTION

The present invention relates to a trench type junction barrier Scthottky diode.

### BACKGROUND OF THE INVENTION

With a wider band-gap, higher dielectric breakdown field strength and higher thermal conductivity compared with traditional Si material, Silicon Carbide (SiC) is promising for the new generation of power semiconductor devices, especially in high voltage, high frequency and high temperature applications. With ten times dielectric breakdown field strength than that of Si, SiC device resistance can be theoretically reduced by three digits with a drift layer thickness decreased to one tenth, and doping concentration increased to one hundred times than that of Si. Furthermore, due to the wide band-gap three times than that of Si, SiC devices can operate at high temperature (150° C.).

The first commercialized device for SiC is Schottky barrier diodes (SBD). When compared with the traditional Si bipolar type PN diodes, SiC SBD diodes have advantages of no reverse recovery current and high frequency capability. With only one carrier conducting current in forward mode, it can eliminate the minor carrier injection phenomenon which is the condition for Si PN diodes. As a result, the reverse recovery process is eliminated upon switching and the switching loss can be reduced drastically.

For pure Schottky barrier diode, the relatively large leakage current is the main problem. Junction barrier Schottky (JBS) diode structure was proposed to address this problem, which combines the advantages of Schottky junction and PN junction diodes. In JBS structure, plurality of P regions is disposed between Schottky regions. The depletion layer diffuses from PN junction to exhibit pinch-off below the Schottky contact in reverse blocking mode, which can provide electric field shielding effect. As a result, the electric field strength at the Schottky interface can be reduced and the diode leakage current can be decreased subsequently.

The electric field shielding effect can be enhanced by increasing the PN junction depth. However, due to the strong lattice of SiC material, the ion implantation depth is usually being restricted to be less than 1 μm. Recently, trench type junction barrier Schottky diode structure is proposed as shown in FIG. 5. With the introduction of trench, the p-type ions can be implanted into the side wall and bottom of the trench, and the subsequent PN junction can be deeper than 1 μm. However, in normal forward mode, only the Schottky junction in JBS structure can conduct current since the PN junction has a high onset voltage due to the wide band-gap of SiC. The depletion region from the PN junction will shrink the conduction channel to be much narrower than the design width of the Schottky region. As a result, with a deeper PN junction, the device forward performance will be sacrificed due to a higher channel resistance between adjacent P regions.

Therefore, there remains a new and improved trench type junction barrier Schottky diode to increase forward current density without deterioration of the reverse voltage. In the present invention, the PN junction in FIG. 6 will be replaced with a Schottky junction on the side wall of the trench 3, while remaining the P region 4 in the bottom of the trench for the reverse benefits.

### SUMMARY OF THE INVENTION

In the trench type junction barrier Schottky diode, in order to increase forward current density while keep the strong electric field shielding effect introduced by the deep PN junction, it is necessary to increase the effective conduction area. The present invention in FIG. 1 replaces the PN junction with Schottky junction for the trench. A Schottky metal is filled into the trench to form Schottky junction between each trench 3 and epitaxial layer 2, and thus introduce a second conduction path in addition to the original Schottky junction on the top of the epitaxial layer 2. On the other hand, the P-type region 4 at the bottom of the trench is remained to keep the electric field shielding effect. As a result, the forward current density is supposed to be increased without deterioration of the reverse voltage.

In the trench structure, the depth of the Schottky metal layer and P-type implant layer can be altered in different condition. It can introduce a new degree of freedom to obtain a better trade-off between the forward current density and reverse electric field shielding effect. In FIG. 1, the structure shows a deeper Schottky metal layer compared with P-type layer. In FIG. 2, the structure shows a same depth design of the Schottky metal layer and P-type layer. In FIG. 3, the structure shows a shallower Schottky metal layer when compared with the P-type layer.

A method of manufacturing a trench type junction barrier Schottky diode comprising: a silicon carbide substrate containing an impurity and having a first conduction type; an epitaxial layer of a first conduction type formed over the substrate and having an impurity concentration lower than that of the substrate; a group of first trenches each formed in the surface of the epitaxial layer and having a bottom and a lateral side; a second conduction type impurity region formed in the bottom side of the first trench; a Schottky junction region put on the lateral side of and between the first trenches of the group; an ohmic contact formed on the rear face of the substrate, the method including: forming trenches with vertical walls by dry etching; and ion implanting a second conduction type impurity into the bottom of the first trench vertically to the surface of the substrate, thereby forming a second conduction type impurity region in the bottom of the first trench; depositing the first Schottky metal onto the surface of the epitaxial layer to form Schottky junction on the top of the epitaxial layer; filling the first Schottky metal into the first trench, thereby forming Schottky junction in the trench.

According to the aspect of the invention, even when the PN junction depth is increased intending to enhance the electric field shielding effect and lower the leakage current, forward current density can still be increased with the additional conduction path through the Schottky junction in the trench.

### BRIEF DESCRIPTION OF THE DRAWINGS

FIG. 1 is a cross sectional structural view of a trench type junction barrier Schottky diode with deeper trench compared with the P-type layer.

FIG. 2 is a cross sectional structural view of a trench type junction barrier Schottky diode with the same depth design of the trench and P-type layer.

FIG. 3 is a cross sectional structural view of a trench type junction barrier Schottky diode with shallower trench compared with the P-type layer.

FIG. 4A to 4E are explanatory views for manufacturing processes of the trench type junction barrier Schottky diode.

FIG. 5 is a flow diagram illustrating a method for manufacturing a SiC trench type Schottky diode.

FIG. 6 is a prior art showing a cross sectional structural view of an existent trench type junction barrier Schottky diode.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

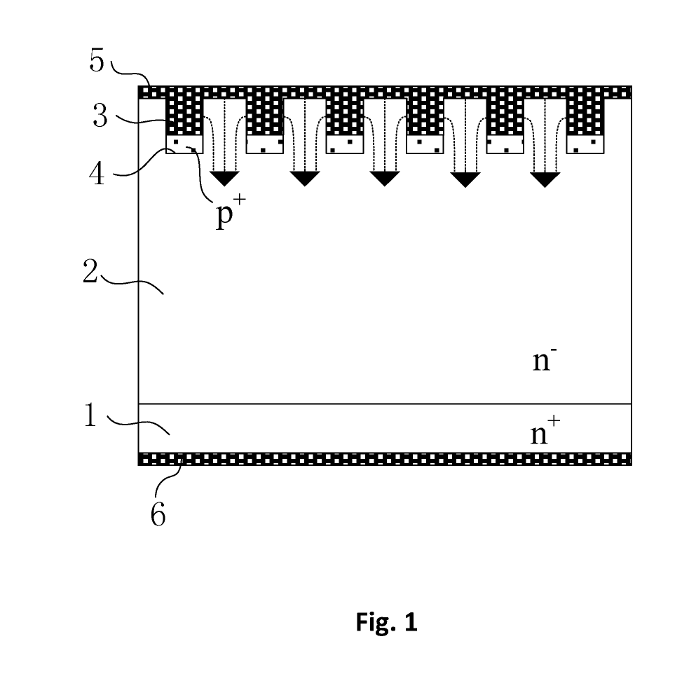

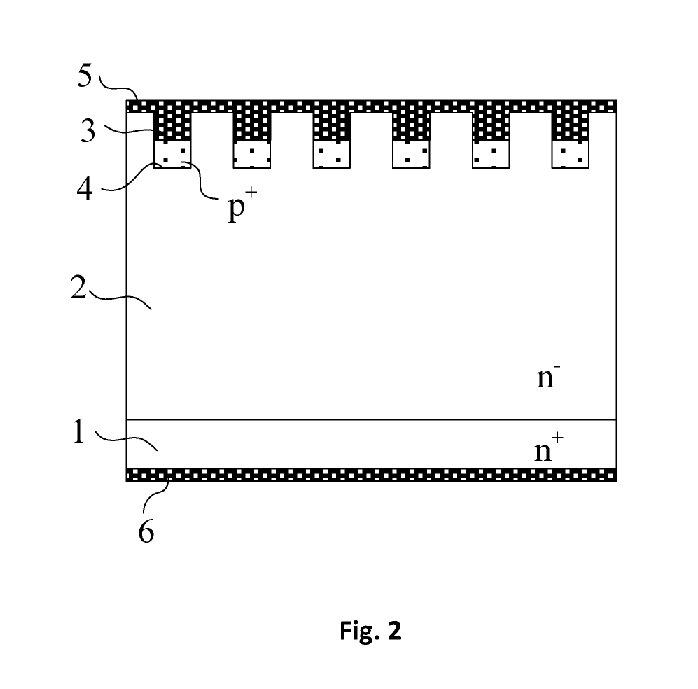

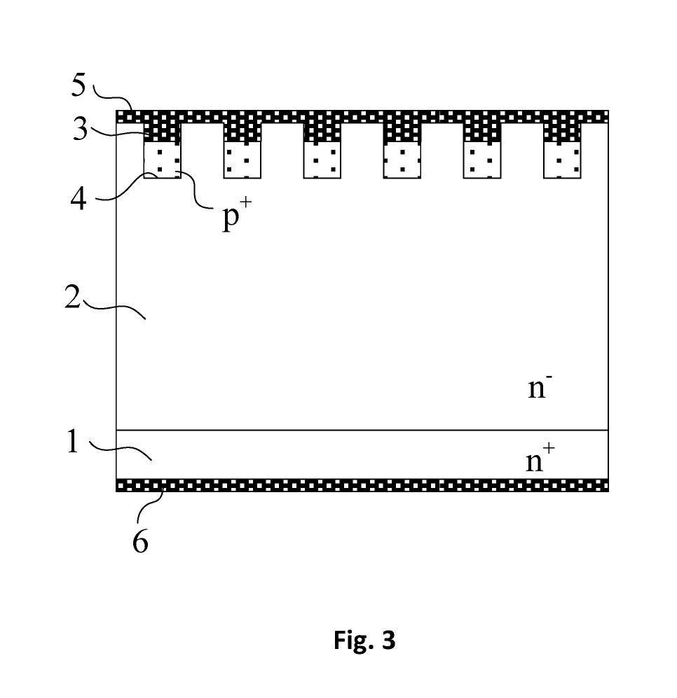

In one aspect as shown in FIGS. 1 to 3, a cross sectional view of a SiC trench type junction barrier Schottky diode is illustrated. More specifically, a SiC trench type Schottky diode is disclosed in the present invention, which includes a substrate 1, an epitaxial layer 2, a trench 3, an implantation layer 4, a Schottky contact metal 5 and an ohmic contact metal 6.

In one embodiment, the material selected for the ohmic contact metal 6 can be nickel, silver or platinum. The substrate 1 produced from N⁺ type SiC can be located on the top of ohmic contact metal 6. The epitaxial layer 2 produced from N⁻ type SiC can be disposed on the top of the substrate. In another embodiment, the trench 3 is produced by etching the epitaxial layer 2 with depth of about 1 to 50000 angstrom. The implantation layer 4 can be produced by ion implantation into the trench bottom from P-type material such as boron or aluminum. In one embodiment, the thickness of the implant layer 4 is about 1 to 10000 angstrom.

In a further embodiment, the Schottky contact metal 5 is located on the top of the epitaxial layer 2 and a Schottky junction is formed between the the Schottky contact metal 5 and the epitaxial layer 2. More specifically, the trench 3 is filled with the Schottky contact metal 5 and a Schottky junction is formed between the trench 3 and the epitaxial layer 2.

It is important to note that without a P-type region on the side walls, the trench 3 is formed as N-type Schottky contact, providing a Schottky junction between the trench 3 and the epitaxial layer 2. As a result, in addition to the original Schottky contact on the top of the epitaxial layer 2, there could be a second conduction path through the trenches 3 in forward operation mode. The device forward current density can be increased with a subsequent larger effective conduction area. Moreover, the P-type region in the bottom of the trench is remained for the reverse benefits with the electric field shielding effects.

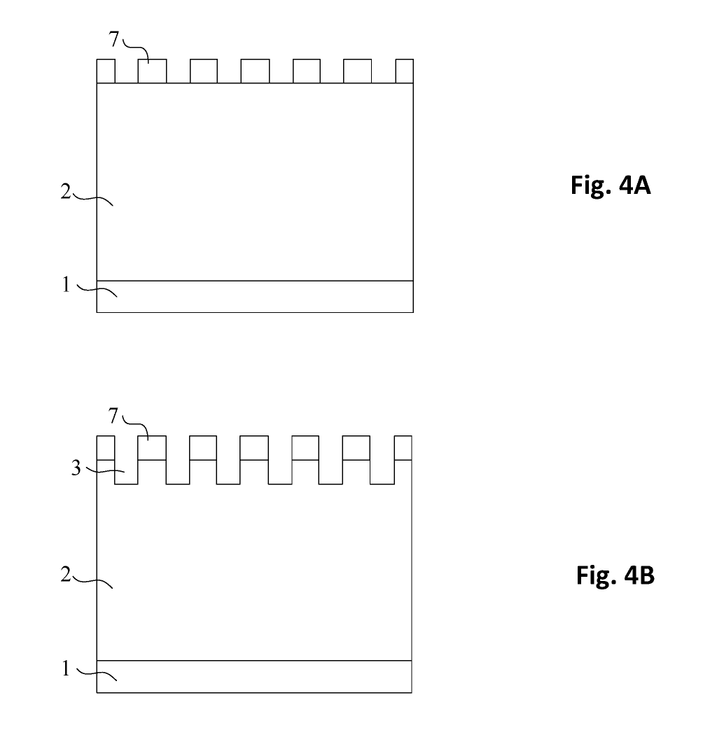

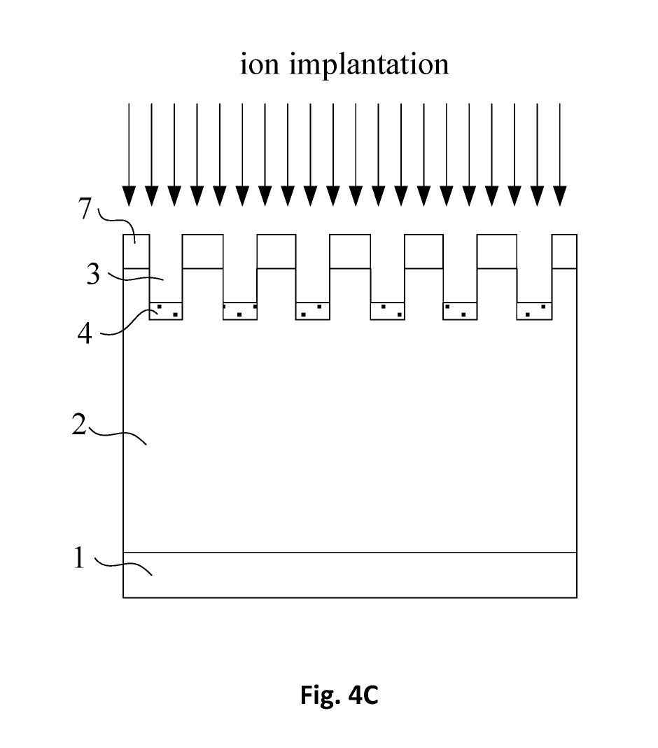

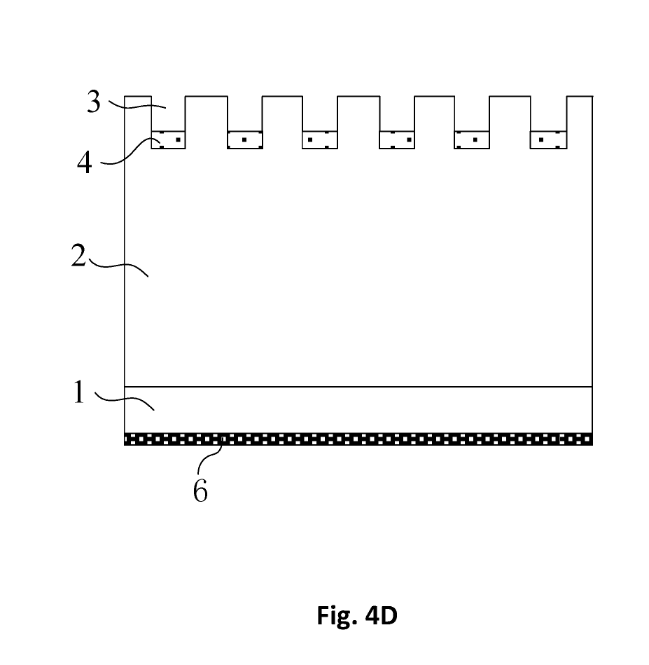

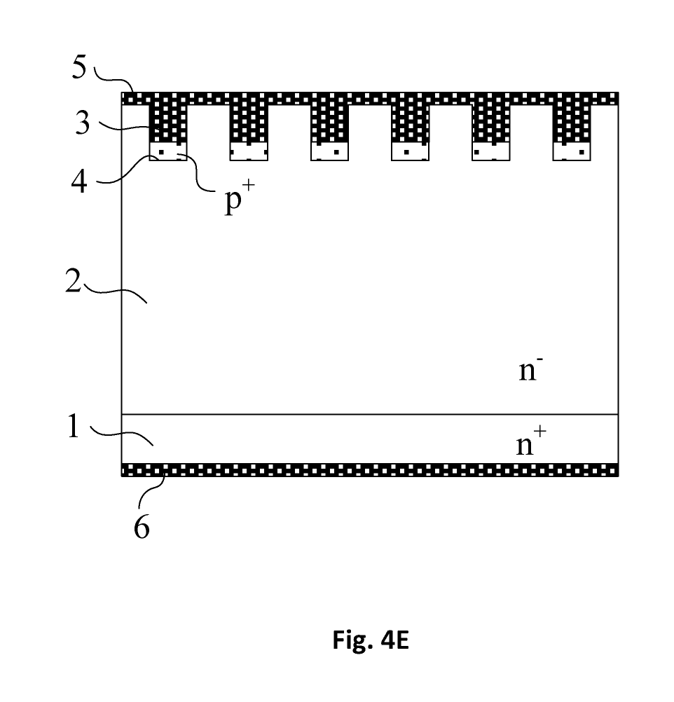

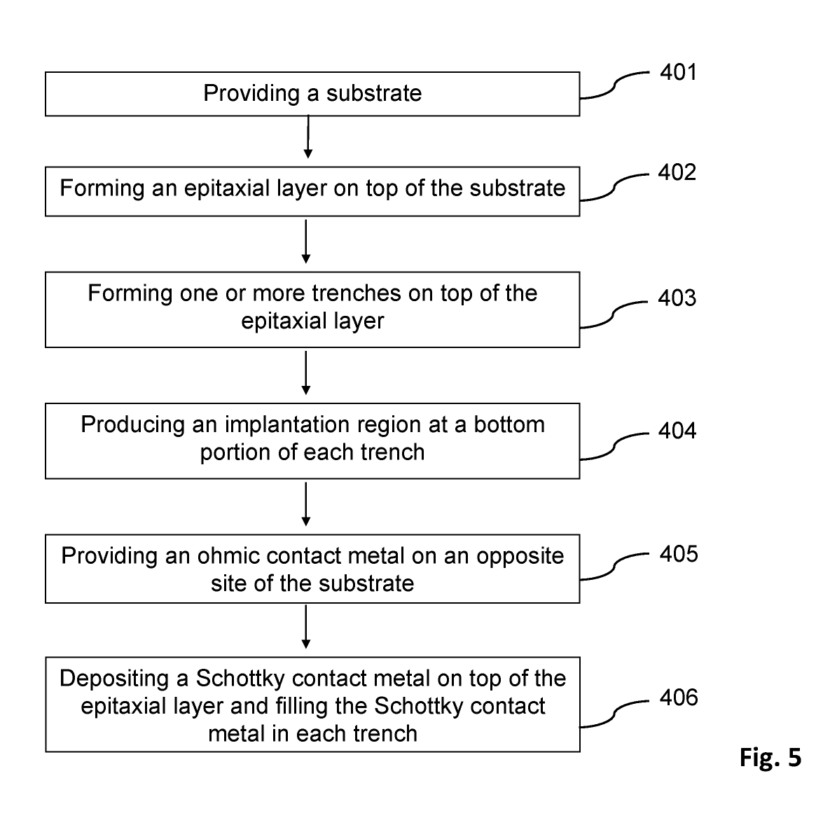

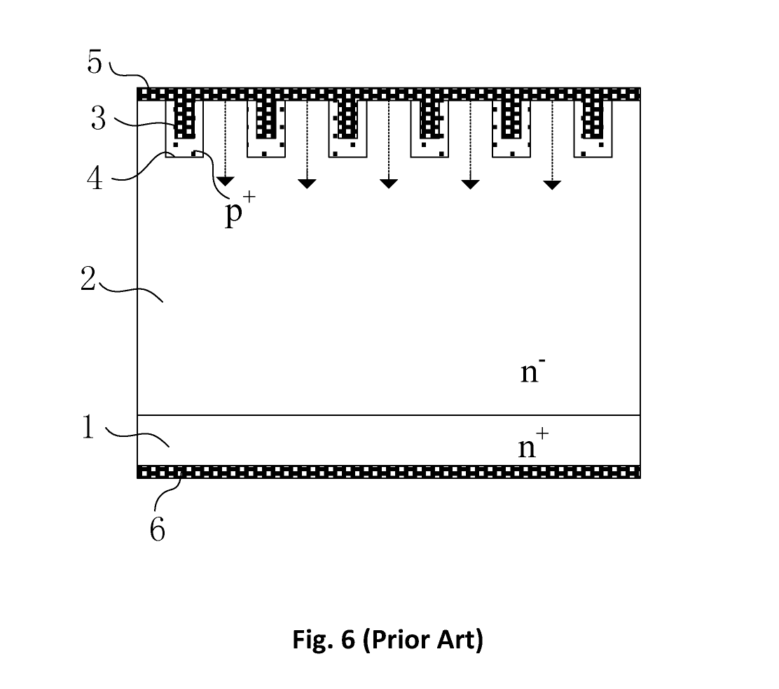

In another aspect, referring to FIGS. 4A-4E and 5, a method for manufacturing a SiC trench type Schottky diode may include steps of step 401: providing a substrate 1, step 402: forming an epitaxial layer 2 on top of the substrate 1, step 403: forming one or more trenches 3 on top of the epitaxial layer 2, step 404: producing an implantation region 4 at a bottom portion of each trench 3, step 405: providing an ohmic contact metal 6 on an opposite site of the substrate 1, and step 406: depositing a Schottky contact metal 5 on top of the epitaxial layer 2 and filled in each trench 3.

In one embodiment, the step 401 of forming the substrate 1 involves using N⁺ type SiC as a substrate, and the step 402 of forming an epitaxial layer 2 involves forming an epitaxial layer made from N⁻ type SiC on the top of the substrate. Furthermore, the step 403 of forming trench 3 may include a step of patterning and etching the epitaxial layer 2 to form trenches 3 on the epitaxial layer 2, and the step 404 of producing an implantation region 4 may include a step of doping P-type impurity into the bottom of the trench.

In another embodiment, the step 405 of providing an ohmic contact metal 6 involves providing an ohmic contact metal below the substrate 1, and a Schottky junction is formed by depositing the Schottky contact metal on top of the epitaxial layer 2, and the Schottky junction is formed between the Schottky contact metal 5 and the epitaxial layer 2. It is noted that each trench 3 is also filled the Schottky contact metal 5 to form a Schottky junction between the trench 3 and the epitaxial layer 2.

It is important to note that in the present invention, P-type impurity is only doped into the bottom of the trench 3 of the trench type Schottky diode to reduce the electric field strength and the leakage current at the Schottky junction. Moreover, each trench 3 is processed as N-type Schottky contact, which can contribute current conduction capability in forward mode to reduce the device resistance.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A Schottky diode comprising:
a substrate;
an epitaxial layer deposited on one side of the substrate;
one or more trenches formed on top of the epitaxial layer;
an implantation region at a bottom portion of each trench;
an ohmic contact metal deposited on the other side of the substrate; and
a Schottky contact metal deposited onto the epitaxial layer and filled each trench to form a Schottky junction between the Schottky contact metal and the epitaxial layer, and between each trench and the epitaxial layer.

2. The Schottky diode of claim 1, wherein the substrate is made by N⁺ type Silicon Carbide (SiC) and the epitaxial layer is made by N⁻ type SiC.

3. The Schottky diode of claim 1, wherein each trench is formed by etching the epitaxial layer with a depth ranging from 1 to 50000 angstrom.

4. The Schottky diode of claim 1, wherein the implantation region is formed by ion implantation into a bottom portion of the trench bottom with P-type material such as boron or aluminum.

5. The Schottky diode of claim 4, wherein thickness of the implantation region is ranging from 1 to 10000 angstrom.

6. The Schottky diode of claim 1, wherein the ohmic contact metal is selected from nickel, silver or platinum.

7. A method for manufacturing a Schottky diode comprising steps of:
providing a substrate,
depositing an epitaxial layer on top of the substrate,
forming one or more trenches on top of the epitaxial layer,
producing an implantation region at a bottom portion of each trench,
providing an ohmic contact metal on an opposite site of the substrate, and
depositing a Schottky contact metal on top of the epitaxial layer and filled into each trench to form a Schottky junction between the Schottky contact metal and the epitaxial layer, and between each trench and the epitaxial layer.

8. The method for manufacturing a Schottky diode of claim 7, wherein the substrate is made by N⁺ type Silicon Carbide (SiC) and the epitaxial layer is made by N⁻ type SiC.

9. The method for manufacturing a Schottky diode of claim 7, wherein the step of forming one or more trenches includes a step of patterning and etching the epitaxial layer to form said one or more trenches.

10. The method for manufacturing a Schottky diode of claim 7, wherein the step of producing an implantation region includes a step of doping P-type impurity into the bottom of each trench.

11. The method for manufacturing a Schottky diode of claim 7, wherein the ohmic contact metal is selected from nickel, silver or platinum.
